(19) United States
(12) Patent Application Publication
(10) Pub. No.: US 2023/0395359 A1
(43) Pub. Date: Dec. 7, 2023

(54) COLD EDGE LOW TEMPERATURE ELECTROSTATIC CHUCK

(71) Applicant: Lam Research Corporation, Fremont, CA (US)

(72) Inventors: Ambarish Chhatre, Danville, CA (US); Patrick Chung, Tracy, CA (US); Dan Marohl, San Jose, CA (US); Craig A. Rosslee, San Jose, CA (US); David A. Setton, Danville, CA (US); Mohammad Sohail Shaik, Andra Pradesh (IN)

(21) Appl. No.: 18/032,154

(22) PCT Filed: Sep. 9, 2021
(86) PCT No.: PCT/US2021/049632

§ 371 Date: Apr. 14, 2023

Related U.S. Application Data
(60) Provisional application No. 63/094,291, filed on Oct. 20, 2020.

(51) Int. Cl. H01J 37/32; H01L 21/67; H01L 21/683; H01L 21/687

(52) U.S. Cl. CPC H01J 37/32724; H01L 21/67103; H01L 21/67109; H01L 21/67248; H01L 21/6833; H01L 21/68735; H01L 21/68785

(57) ABSTRACT

An electrostatic chuck is provided. In one example, the electrostatic chuck includes a base plate, a bond layer disposed over the base plate, a ceramic plate, and a heater. The ceramic plate includes a bottom surface disposed over the bond layer and a raised top surface for supporting a substrate. The raised top surface includes an outer diameter. The heater is disposed between the bottom surface of the ceramic plate and the bond layer. The heater element includes an inner heating element and an outer heating element. The inner heating element is arranged in a central circular area adjacent to the bottom surface of the ceramic plate and the outer heating element is arranged in an annular area that surrounds the central circular area and is adjacent to the bottom surface of the ceramic plate. An outer diameter of the outer heating element is inset from an annual heater setback region of the ceramic plate. The annular heater setback region is between the outer diameter of the raised top surface and the outer diameter of the outer heating element. The base plate includes a plurality of cooling channels. The plurality of cooling channels is disposed below the inner heating element, below the outer heating element, and below the annular heater setback region. Each of plurality of the cooling channels are configured to flow a cooling fluid to cause thermally conductive cooling in the annular heater setback region of the ceramic plate.

### FIELD OF THE INVENTION

The present embodiments relate to semiconductor fabrication, and more particularly, to electrostatic chuck structures and methods for controlling temperature provided to wafer surfaces when supported by an electrostatic chuck used in plasma process chambers.

### BACKGROUND

### Description of the Related Art

Many modern semiconductor chip fabrication processes such as plasma etching processes are performed within a plasma processing chamber in which a substrate, e.g., wafer, is supported on an electrostatic chuck (ESC). In plasma etching processes, the wafer is exposed to a plasma generated within a plasma processing volume. Plasma contains various types of radicals, as well as positive and negative ions. The chemical reactions of the various radicals, positive ions, and negative ions are used to etch features, surfaces and materials of a wafer.

In some cases, temperature control of the wafer during plasma etching processing operations is one factor that can influence the outcome of the processed wafer. For example, during etching operations, the process conditions may generate a lot of heat on a wafer which affects the etch rate and may cause non-uniformity of features formed on the wafer. To provide for better control of the wafer temperature during the plasma etching processing operation, there is a need for ESC designs that can provide for better temperature control for improving the quality of the processed wafer and reduce the overall cost of the system and its operating costs.

It is in this context that embodiments of the inventions arise.

### SUMMARY

Implementations of the present disclosure include devices, methods, and systems for controlling temperature variations in wafers when supported on an electrostatic chuck (ESC) of a plasma process chamber during plasma etching processing. In some embodiments, an ESC includes a base plate, a bond layer disposed over the base plate, a ceramic plate disposed over the bond layer, and a heater positioned between the ceramic plate and the bond layer. In one embodiment, the base plate includes a plurality of cooling channels that are configured to flow a cooling fluid which causes thermally conductive cooling of the ceramic plate and also in an annular heater setback region of the ceramic plate.

In another embodiment, the bond layer is configured to be thin or have a reduced thickness which can help facilitate the thermal conductive cooling of the annular heater setback region of the ceramic plate. As a result, a base plate with deep and wide cooling channels and a bond layer with a reduced thickness may result in a high heat transfer coefficient, which in turn causes an increase in thermally conductive cooling in the annular heater setback of the ceramic plate. In one embodiment, reference to a “cold edge” means that the temperature in the annular heater setback is engineered to be lower or colder than the temperature in other parts of the ceramic chuck that lie under the inner and outer heaters.

By way of the structure construction of the annular heater setback, the temperature along the edge of the wafer can be maintained at a lower temperature than other areas of the wafer that extend toward the center of the wafer. By way of example, at the start of the annular heater setback the lower temperature may be controlled to be about 2-3 degrees C. lower than areas overlying a heater, and the temperature may be further reduced up to about 10 degrees C. or more at the outer diameter of the annular heater setback, relative to areas overlying a heater.

In one embodiment, the heater may include an inner heating element and an outer heating element that are configured to provide the ESC with two temperature zones (e.g., annular area temperature zone, and central circular area temperature zone). Accordingly, during the processing of the wafer, the cold edge temperature region helps control temperature cooling of the wafer along its edges and keeps it at a desired temperature to help improve the etch rate and profile of features formed on the wafer. As will be described below, the amount of cooling provided by the cold edge may vary and can be controllably adjusted by programming changes to a chiller set point of a chiller.

In one embodiment, an etch process may be run that requires rapid alternating process for silicon etch which is highly exothermic in nature. The process conditions generate lot of heat on the wafer which affects etch rate and profile. It has been observed that keeping the wafer edge at a reduced temperature, relative to other parts of the wafer surface, assists to improve etch rate and uniformity on the wafer. In some cases, this improvement in etch rate and uniformity is needed to meet stringent requirements for bottom critical dimension (CD) profiles of etched features. In this context, a bottom CD refers to the etch profile produced during etching near a bottom region of an etch feature. By lowering the temperature of the edge of the wafer, it was observed that the bottom CD of features formed near or around the edge of the wafer maintained a profile similar to features formed in other parts of the wafer, i.e., away from the edge region. As a result, improvements in etch uniformity are achieved.

As mentioned above, the lower temperature in the cold edge of the wafer is facilitated by a combination of structural advances in the ESC design. Broadly speaking, one structural feature is keeping the outer heater from extending over the annular heater setback, one structural feature is reducing a thickness of a bond layer between the base plate and the ceramic plate, and another structural feature is reducing a thickness of material in the base plate between the bond layer and cooling channels. Collectively, these structural features assist to transfer additional cooling to the annular heater setback, while still providing heating to a central circular area temperature zone and an annular area temperature zone.

Advantageously, the structure of the ESC provides for controlling the temperature of the annular heater setback region, i.e., maintaining it cooler than other zones by flowing cooling fluid using a chiller controlled by a chiller set-point. To further control the temperature at the annular heater setback region, it is possible to adjust the temperature of the chiller set-point. For instance, if the annular heater setback region needs to be cooler, the chiller set-point can be set to flow cooler temperatures. In some embodiments, since the chiller set-point flows cooling fluid in the cooling channels under most of the wafer, it is possible to increase the heater temperatures if the cooling is increased by the cooling fluid. This allows for cooling the cold edge while maintaining other parts of wafer surface constant.

As a further advantage, the structure of the ESC, having only two heaters, reduces the complexity of other designs that require more heaters to achieve three or more temperature zones. Reducing the number of heaters further assists in reducing costs associated with added alternating current (AC) boxes, control systems and heater RF filters.

In one embodiment, an ESC is disclosed. The ESC includes a base plate, a bond layer disposed over the base plate, a ceramic plate, and a heater. The ceramic plate includes a bottom surface disposed over the bond layer and a raised top surface for supporting a substrate. The raised top surface includes an outer diameter. The heater is disposed between the bottom surface of the ceramic plate and the bond layer. The heater includes an inner heating element and an outer heating element. The inner heating element is arranged in a central circular area adjacent to the bottom surface of the ceramic plate and the outer heating element is arranged in an annular area that surrounds the central circular area and is adjacent to the bottom surface of the ceramic plate. An outer diameter of the outer heating element is inset from an annual heater setback region of the ceramic plate. The annular heater setback region is between the outer diameter of the raised top surface and the outer diameter of the outer heating element. The base plate includes a plurality of cooling channels. The plurality of cooling channels is disposed below the inner heating element, below the outer heating element, and below the annular heater setback region. Each of plurality of the cooling channels is configured to flow a cooling fluid to cause thermally conductive cooling in the annular heater setback region of the ceramic plate.

In another embodiment, a method for thermally cooling a region of an electrostatic chuck is disclosed. The electrostatic chuck includes a ceramic plate and a base plate. The method includes providing an inner heating element and an outer heating element between the base plate and the ceramic plate. The outer heating element is positioned away from an annular heater setback region of the ceramic plate. The method includes flowing a cooling fluid along a plurality of cooling channels disposed in the base plate, wherein at least one of the plurality of cooling channels is disposed under the annular heater setback region, the cooling fluid is configured to cause thermal cooling in the annular setback region of the ceramic plate to provide for a cold edge region for a substrate when disposed over the electrostatic chuck. The method includes activating alternating current (AC) heaters that are connected to the outer heating element and the inner heating element. The method includes activating a chiller to operate at a set point temperature. Activating the chiller is configured to control flow of the cooling fluid to thermally cool the annular heater setback region, wherein the outer heating element does not extend into the annular heating setback region.

Other aspects and advantages of the disclosure will become apparent from the following detailed description, taken in conjunction with the accompanying drawings, illustrating by way of example the principles of the disclosure.

### BRIEF DESCRIPTION OF THE DRAWINGS

The disclosure may be better understood by reference to the following description taken in conjunction with the accompanying drawings in which:

FIG. 1A illustrates an embodiment of a capacitive coupled plasma (CCP) processing system utilized for etching operations, in accordance with an implementation of the disclosure.

FIG. 1B illustrates an example of an inductively coupled plasma (ICP) processing system, in accordance with an implementation of the disclosure.

FIG. 2A illustrates an embodiment of an electrostatic chuck for supporting a wafer within a chamber of a plasma processing system, in accordance with an implementation of the disclosure.

FIG. 2B illustrates cross section A-A of the electrostatic chuck shown in FIG. 2A, in accordance with an implementation of the disclosure.

FIG. 3A illustrates an enlarged partial view of a section of the electrostatic chuck shown in FIG. 2B during thermal conductive cooling by a chiller, in accordance with an implementation of the disclosure.

FIG. 3A-1 illustrates a temperature plot of the temperature regions of the ceramic plate and the corresponding temperature transition zone, in accordance with an implementation of the disclosure.

FIG. 4 illustrates an enlarged partial view of a section of the electrostatic chuck shown in FIG. 2B, in accordance with an implementation of the disclosure.

FIG. 5A illustrates an embodiment of a top view of the inner heating element and the outer heating element, in accordance with an implementation of the disclosure.

FIG. 5B illustrates an embodiment of a top view of the electrostatic chuck showing the various temperature zones in the electrostatic chuck, in accordance with an implementation of the disclosure.

FIG. 5C illustrates an embodiment of a top view of the electrostatic chuck showing the heat transfer simulation results of the electrostatic chuck, in accordance with an implementation of the disclosure.

FIG. 6 shows an example schematic of the control system of FIG. 1A, in accordance with an implementation of the disclosure.

### DETAILED DESCRIPTION

The following implementations of the present disclosure provide devices, methods, and systems for controlling temperature variations in wafers when supported on an electrostatic chuck (ESC) of a plasma process chamber during plasma etching processing. The ESC includes various structural features that are configured to help facilitate thermally conductive cooling to reduce and control the heat along various regions of a ceramic plate of the ESC. By reducing and controlling the heat along the ceramic plate such as an annular heater setback region of the ceramic plate, a cold edge temperature region can be provided for a wafer during plasma etching processing. Accordingly, the cold edge temperature region helps control the temperature of the wafer along its edges and keeps it at a desired temperature to help improve the etch rate and profile of etched features.

Some current ESCs may not be optimized for high thermally conductive cooling along a periphery region of the ceramic plate. This may result in undesirable high temperatures along the edge of the wafers during etching processing which can negatively affect etching performance and the profile of the processed wafers. Further, some ESCs may be designed to have three or more temperature zones which requires a greater number of heaters and components (e.g., AC boxes, control systems, heater RF filters, etc.) to achieve the temperature zones. This may result in higher system and operating costs since there are a greater number of components that are needed to operate the ESC and achieve the temperature zones.

In view of these issues, one disclosed embodiment includes an ESC with various structural features that are optimized to facilitate high thermally conductive cooling of the ceramic plate and also in an annular heater setback region of the ceramic plate. In one embodiment, the ESC includes a base plate with a plurality of cooling channels that are configured to flow a cooling fluid which causes thermally conductive cooling of the ceramic plate and also of an annular heater setback region of a ceramic plate of the ESC. In some embodiments, the plurality of cooling channels may be of a rectangular shape and have a specific width and height that are configured to have an optimal contact surface area for the cooling fluid to flow which can help facilitate the thermally conductive cooling in the various regions of the ceramic plate.

In accordance with another embodiment, the ESC includes a bond layer disposed over the base plate. In some embodiments, the bond layer is optimized to be thin or have a reduced thickness which results in high heat transfer coefficient, which in turn facilitates thermally conductive cooling from the base plate to the various regions of the ceramic plate.

In accordance with another embodiment, the ESC includes a heater that has an inner heating element and an outer heating element. As used herein, the inner heating element and the outer heating element are conductive wires that are embedded in the ESC and power is supplied to the heating elements from alternating current (AC) heaters. The inner heating element and the outer heating element can be any shape and configured to form any path in order to meet the desired heating area requirements. The heating elements are disposed between a bottom surface of the ceramic plate and the bond layer and is configured to create two temperature zones (e.g., central circular area temperature zone, annular area temperature zone) in the ESC. In one embodiment, the outer heating element of the heater element does not extend under the annular heater setback region of the ceramic plate so that the outer heating element does not interfere with the thermally conductive cooling caused by the flow of the cooling fluid in the base plate. In one embodiment, the annular heater setback region of the ceramic plate relies on the thermally conductive cooling by the flow of the cooling fluid to create a cold edge temperature region for the wafer.

With the overview above, the following provides several example embodiments based on the figures provided to facilitate understanding of the present disclosure.

The ESC 102 disclosed herein may be used in any number of plasma processing chambers. These include inductively coupled plasma (ICP) processing systems as well as capacitive coupled plasma (CCP) processing systems.

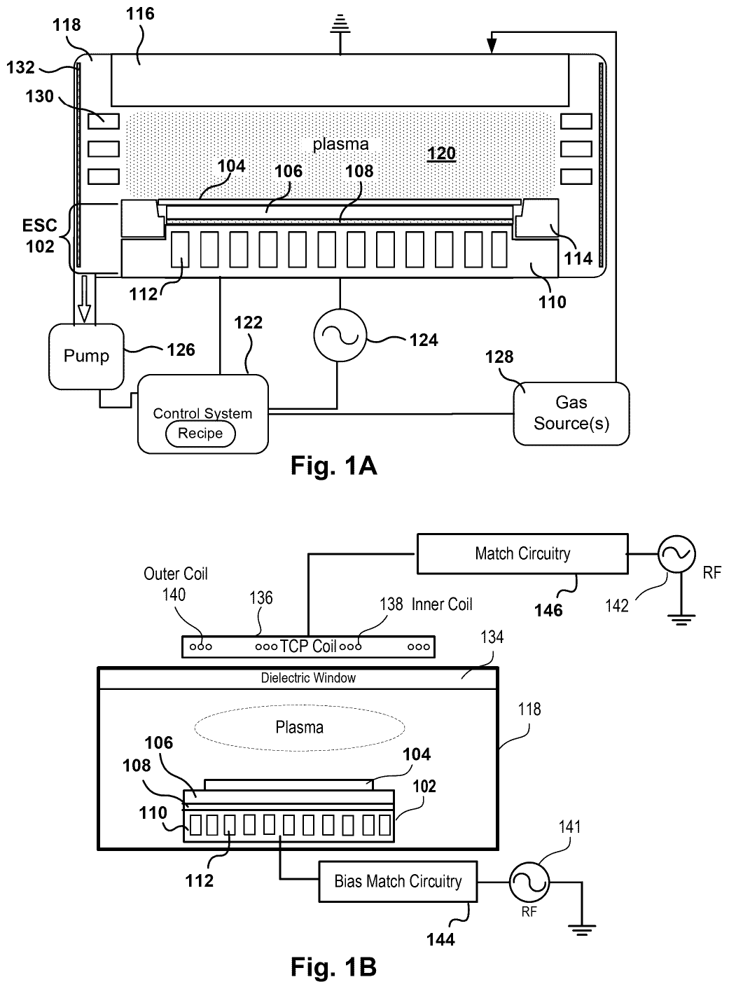

FIG. 1A illustrates an embodiment of a capacitive coupled plasma (CCP) processing system utilized for etching operations. The CCP processing system includes a plasma process chamber 118, a control system 122, a radio frequency (RF) source 124, a pump 126, and one or more gas sources 128 that are coupled to the plasma process chamber 118. The plasma process chamber 118 includes an ESC 102 for supporting a wafer 104, and an edge ring 114. In some embodiments, the plasma process chamber 118 may include confinement rings 130 for confining the plasma 120, and a chamber wall cover 132.

As shown in FIG. 1A, the ESC 102 is located in the plasma process chamber 118. In some embodiments, the ESC 102 includes a ceramic plate 106, a bond layer 108, a base plate 110, and a heater (not shown). The ceramic plate 106 may include a raised top surface that is configured to support a wafer 104 during processing. The bond layer 108 is configured to secure the ceramic plate 106 to the base plate 110. The bond layer 108 also acts as a thermal break between the ceramic plate 106 and the base plate 110. In some embodiments, the base plate 110 may be made of an aluminum material or any other material or combination of materials that can provide sufficient electrical conduction, thermal conduction, and mechanical strength to support operation of the ESC 102. In some embodiments, the base plate 110 includes a plurality of cooling channels 112 that are configured to flow a cooling fluid to cause thermally conductive cooling in the ceramic plate and also in an annular heater setback region of the ceramic plate. In one embodiment, the heater is disposed between the ceramic plate 106 and the bond layer 108. In some embodiments, the heater includes an inner heating element and an outer heating element that are configured to create two temperature zones in the ceramic plate. Broadly speaking, the structural features of the components of the ESC 102 are configured to work together to cause thermally conductive cooling in the ceramic plate and also the annular heater setback region of the ceramic plate which in turn controls the temperature of the wafer 104 during processing. The structural features of the ESC 102 and its components are discussed in greater detail below.

In some embodiments, the control system 122 is used in controlling various components of the CCP processing system. In one example, as shown in FIG. 1A, the control system 122 may be connected to the ESC 102, the RF source 124, the pump 126, and the gas sources 128. The control system 122 includes a processor, memory, software logic, hardware logic and input and output subsystems from communicating with, monitoring and controlling the CCP processing system. In some embodiments, the control system 122 includes one or more recipes including multiple set points and various operating parameters (e.g., voltage, current, frequency, pressure, flow rate, power, temperature, etc.) for operating the system.

As further illustrated in FIG. 1A, the system may include a single RF source 124 or multiple RF sources that are capable of producing frequencies that can be used to achieve various tuning characteristics. As illustrated, the single RF source 124 is connected to the ESC 102 and is configured to provide an RF signal to the ESC 102. In one example, the RF source may produce frequencies ranging of about 27 MHz to about 60 MHz, and have an RF power of between about 50 W and about 10 kW. In another embodiment, the gas source 128 is connected to the plasma process chamber 118 and is configured to inject the desired process gas(es) into the plasma process chamber 118. After providing an RF signal to the ESC 102 and injecting process gas into the chamber 118, plasma 120 is then formed between the upper electrode 116 and the ESC 102. The plasma 120 can be used to etch the surface of the wafer 104.

In some embodiments, the pump 126 is connected to the plasma process chamber 118 and is configured to enable vacuum control and removal of gaseous byproducts from the plasma process chamber 118 during operational plasma processing. In some embodiments, the plasma process chamber 118 includes the upper electrode 116 disposed over the ESC 102. In some embodiments, the upper electrode 116 is electrically connected to a reference ground potential or could be biased or coupled to a second RF source (not shown).

FIG. 1B illustrates an example of an inductively coupled plasma (ICP) processing system. In one configuration, the ICP system is also referred to as a transformer coupled plasma (TCP) processing system. The system includes a plasma process chamber 118 that includes an ESC 102, a dielectric window 134, and a TCP coil 136 (inner coil 138 and outer coil 140). The ESC 102 is configured to support a wafer 104 when present.

In one embodiment, the ESC 102 includes a ceramic plate 106, a bond layer 108, a base plate 110, and a heater (not shown). The bond layer 108 is configured to secure the ceramic plate 106 to the base plate 110. In some embodiments, the base plate 110 includes a plurality of cooling channels 112 that are configured to flow a cooling fluid to cause thermally conductive cooling in the ceramic plate and also in an annular heater setback region of the ceramic plate. In some embodiments, the heater includes an inner heating element and an outer heating element that are configured to create two temperature zones in the ceramic plate.

Further shown is a bias RF generator 141, and an RF generator 142 coupled to the TCP coils 136. In one example chamber, the RF generator 142 operates at a frequency of about 13.56 MHz, and the bias RF generator 141 for the bias operates at about 400 kHz. Further, in this example, the supplied power may go up to about 6 kW, and in some embodiments, the power may be supplied up to 10 kW. As shown, a bias match circuitry 144 is coupled between the RF generator 141 and the ESC 102. The TCP coil 136 is coupled to the RF generator 142 via match circuitry 146, which includes connections to the inner coil (IC) 138, and outer coil (OC) 140. Although not shown, in some embodiments, pumps are connected to the plasma process chamber 118 to enable vacuum control and removal of gaseous byproducts from the chamber during operational plasma processing.

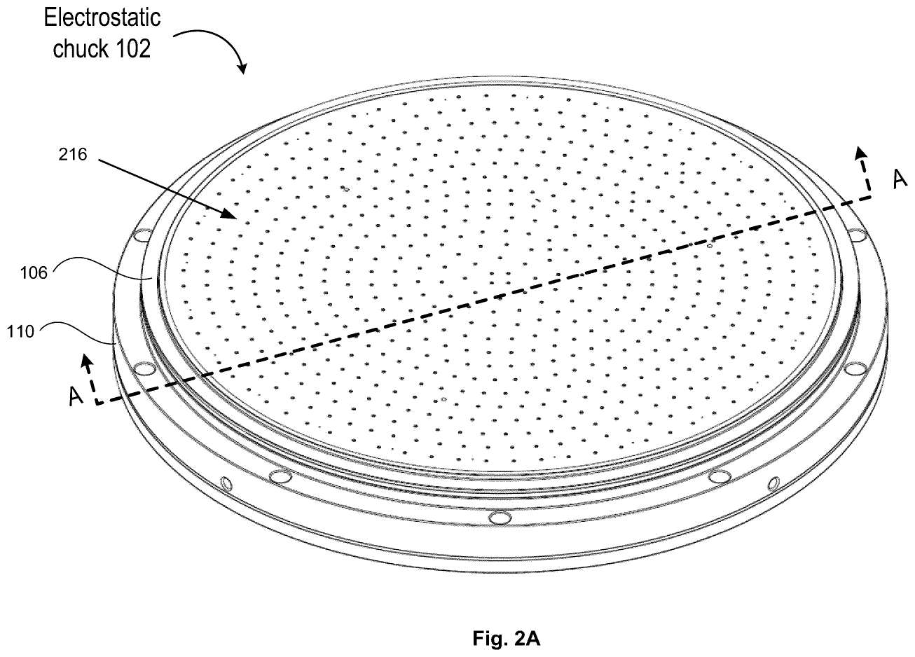

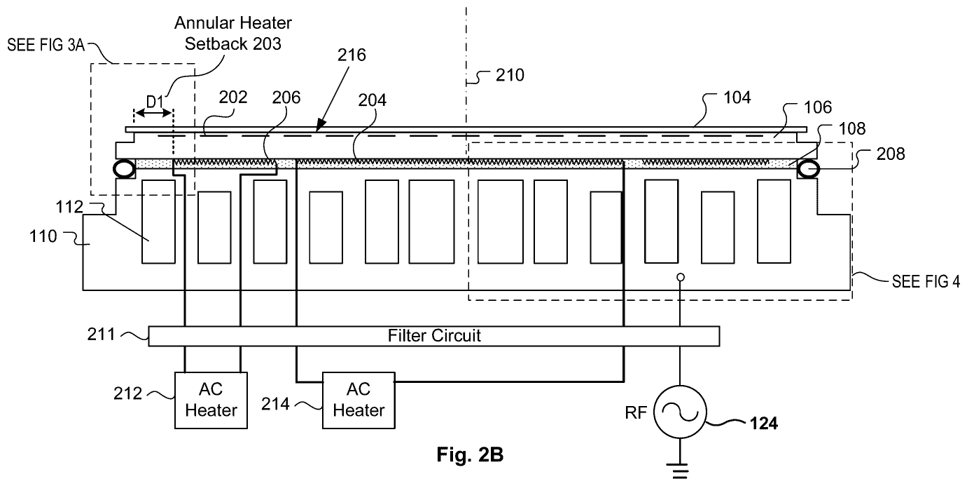

FIG. 2A illustrates an embodiment of an ESC 102 for supporting a wafer 104 within a chamber of a plasma processing system. As shown, the ESC 102 includes a base plate 110, a bond layer 108 (not shown) disposed over the base plate 110, and a ceramic plate 106 disposed over the bond layer 108 with a raised top surface 216 for supporting the wafer 104. In one embodiment, the raised top surface 216 of the ceramic plate 106 includes an area configured to support the wafer 104 during processing. In some embodiments, the raised top surface 216 of the ceramic plate 106 is formed by co-planar top surfaces of multiple raised structures referred to as minimum contact area points that are configured to support the wafer 104 during processing. With the wafer 104 supported by the minimum contact area points during processing, the regions between the sides of the minimum contact area points provide for flow of a fluid, such as helium gas, against the backside of the wafer 104 for enhanced temperature control of the wafer 104 according to some embodiments. In other embodiments, control systems for lifting the wafer 104 off of the ESC 102 can also be provided.

FIG. 2B illustrates cross section A-A of the ESC 102 shown in FIG. 2A. As shown, the ESC 102 includes a ceramic plate 106, a bond layer 108, a base plate 110, clamp electrodes 202, an inner heating element 204, and an outer heating element 206. In some embodiments, the ceramic plate 106 includes a raised top surface 216 that is configured to support a wafer 104 during processing. The ceramic plate 106 includes an annular heater setback region 203 that is defined by distance D1. As shown, distance D1 extends from an outer diameter of the raised top surface 216 of the ceramic plate 106 to an outer diameter of the outer heater 206. In one embodiment, distance D1 is between about 1 mm and about 20 mm, or between about 2 mm and about 20 mm In another embodiment, the distance D1 is between about 3 mm and 7 mm, and in yet another embodiment is about 5 mm. In some embodiments, the annular heater setback region 203 is configured to provide a cold edge temperature region for the wafer 104 when the wafer 104 is disposed over the raised top surface 216 during processing.

In some embodiments, the ceramic plate 106 includes one or more clamp electrodes 202 that are used to generate an electrostatic force for holding the wafer 104 to the raised top surface 216 of the ceramic plate 106. In some embodiments, the clamp electrodes 202 can include two separate clamp electrodes 202 that are configured for bipolar operation in which a differential voltage is applied between the two separate clamp electrodes to generate an electrical force for holding the wafer 104 on the raised top surface 216 of the ceramic plate 106. In other embodiments, mechanical clamps can be used for holding the wafer 104 to the raised top surface 216 of the ceramic plate 106.

In some embodiments, the bond layer 108 is disposed between the ceramic plate 106 and the base plate 110 and is configured to secure the ceramic plate to the base plate. The bond layer 108 also acts as a thermal break between the ceramic plate 106 and the base plate 110. The bond layer 108 may be made from a silicone material or any other type of material that has a high heat transfer coefficient to facilitate the thermally conductive cooling of the ceramic plate and the annular heater setback region 203. In some embodiments, the bond layer 108 is configured to have a thin or reduced thickness to facilitate the flow of the thermally conductive cooling from the base plate.

As further illustrated in FIG. 2B, the inner heating element 204 and the outer heating element 206 are disposed between a bottom surface of the ceramic plate 106 and the bond layer 108. In one embodiment, alternating current (AC) heater 212 is connected to the outer heater element 206 is and alternating current (AC) heater 214 is connected to the inner heating element 204. The AC heaters are configured to deliver power to the inner heating element 204 and the outer heating element 206. When the AC heaters are activated, the inner heating element 204 and the outer heating element 206 produces heat which in turn provides the ESC with a central circular area temperature zone and an annular area temperature zone, respectively. For example, in one embodiment, the inner heating element 204 is arranged within a central circular area in a concentric manner which initiates at a point proximate to the centerline 210 and extends circularly outward and away from the centerline 210 resulting in the inner heating element having an outer diameter of about 230 mm. Accordingly, when the AC heater 214 is activated, the inner heating element 204 produces heat which in turn results in the ESC having a central circular area temperature zone. In another embodiment, the outer heating element 206 is arranged in an annular area that surrounds the central circular area. In some embodiments, the outer heating element 206 extends circularly and has an inner diameter of approximately 236 mm and an outer diameter of approximately 285 mm. Depending on the selected dimension D1 of the annular heater setback 203, the outer diameter of the outer heater element 206 may be adjusted. Accordingly, when the AC heater 212 is activated, the outer heater element 206 produces heat which in turn results in the ESC having an annular area temperature zone.

As further illustrated in FIG. 2B, the base plate 110 is disposed below the ceramic plate 106 and the bond layer 108. In one embodiment, the base plate 110 may be made out of a conductive material such as aluminum. In some embodiments, the base plate 110 can be used as a heat exchanger to cool the ceramic plate and the annular heater setback region 203 of the ceramic plate as cooling fluid is pumped through the cooling channels 112. In some embodiments, cooling channels 112 are circularly arranged within the base plate 110 in a concentric manner. For example, the cooling channels 112 may begin at a point proximate to the center point of the base plate and extend circularly outward toward the periphery of the base plate in a concentric manner. Accordingly, the arrangement of the cooling channels 112 may extend from the center point of the base plate toward a point proximate to the periphery of the base plate. As such, when cooling fluid flows through the cooling channels 112, it navigates across various regions of the base plate which causes thermally conductive cooling of the ceramic plate and also in the annular heater setback region of the ceramic plate. In some embodiments, each of the cooling channels 112 may have the same or different size, shape, geometry, volume, surface area, or any configuration that meets the thermally conductive cooling requirements of the ceramic plate. For example, the cooling channels 112 may be configured to have a specific contact surface area and volume to facilitate a specific flow rate and amount of cooling fluid to flow through the cooling channels 112.

In some embodiments, the ESC 102 includes a perimeter seal 208 disposed between a bottom surface of the ceramic plate 106 and a top surface of the base plate 110. The perimeter seal 208 is further disposed along a radial perimeter of the bond layer 108 and radial perimeter of a raised top surface of the base plate 110. In one embodiment, the perimeter seal 208 is configured to prevent entry of plasma 120 constituents and process by-product materials to interior regions at which the ceramic plate 106 and base plate 110 interface with the bond layer 108.

In some embodiments, a filter circuit 211 is connected to the AC heater 212, the AC heater 214, and the RF source 124. The filter circuit 211 is configured to prevent the AC heaters from burning out when the RF source 124 is active. For example, when the RF source 124 is active and delivering power to the ESC 102, the filter circuit 211 is configured to block RF return currents back to the AC heaters.

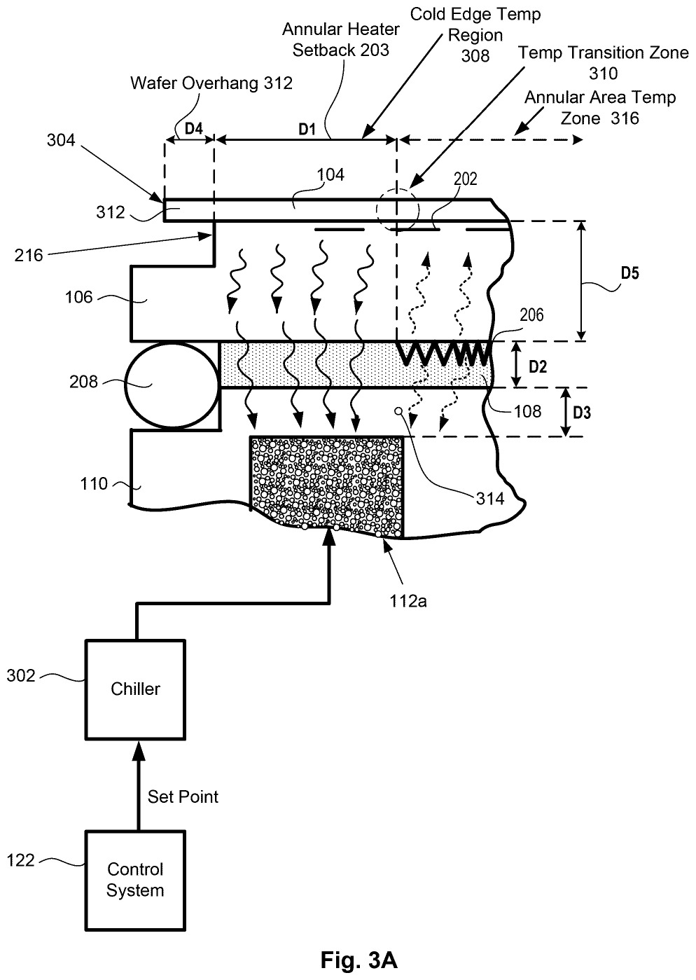

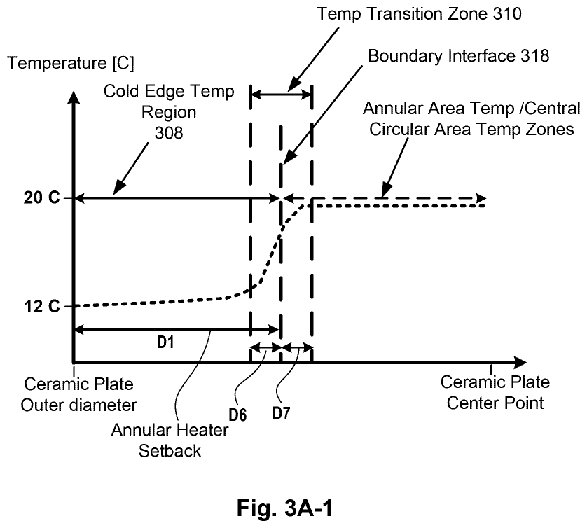

FIG. 3A illustrates an enlarged partial view of a section of the ESC 102 shown in FIG. 2B during thermal conductive cooling by a chiller 302. As shown, the control system 122 is connected to the chiller 302 and configured to activate the chiller 302 to operate at a set point temperature. In some embodiments, the control system 122 continuously monitors the operation of the chiller 302 and ensures that the chiller 302 stays within range of the set point temperature. When the chiller 302 is activated, the chiller 302 is configured to flow a cooling fluid through the cooling channels 112 of the base plate 110 to cause thermally conductive cooling of the ceramic plate 106 and the annular heater setback 203 of the ceramic plate 106. In various embodiments, various types of cooling fluid can be used, such as water or a coolant liquid such as fluorinert. The thermally conductive cooling of the annular heater setback 203 of the ceramic plate 106 creates a cold edge temperature region 308 along the periphery region of the ceramic plate which maintains the temperature of the wafer along its edges at a lower temperature than other regions of the wafer.

In one example, when the chiller 302 is activated, cooling fluid exists the chiller 302 at a set-point temperature and is pumped through the cooling channels 112 of the base plate 110. As the cooling fluid passes through the cooling channels 112, the cooling fluid reduces the temperature at various regions of the base plate 110 and the ceramic plate 106 by thermal conductive cooling. The heaters increase the temperature in the area around them, counteracting the cooling due to the cooling fluid. Accordingly, the temperature along the annular heater setback region 203 of the ceramic plate is lower than at the regions of the ceramic plate where the heaters are located. After the cooling fluid exits the base plate 110, the cooling fluid returns to the chiller 302 at a temperature that is greater than the set-point temperature where it is cooled by the chiller 302.

In another embodiment, to further control the temperature at the annular heater setback region 203, it is possible to adjust the temperature of the chiller set-point. For example, if the temperature along the annular heater setback region 203 needs to be cooler, the set point temperature of the chiller 302 can be set to flow at cooler temperatures. In some embodiments, since the chiller set point flows cooling fluid in the cooling channels 112 under most of the wafer 104, it is possible to increase the temperature of the heaters (e.g., inner heating element 204, and outer heating element 206) if the cooling is increased by the cooling fluid. This allows for cooling the annular heater setback region 203 while maintaining the temperature of other parts of wafer 104 constant. In some embodiments, temperature data related to the annular heater setback region 203 of the ceramic plate 106 can be continuously measured to determine if the temperature data is within a temperature value projected based on the set point temperature. This can help control the temperature of the wafer and maintain desired process conditions.

As shown in the enlarged partial view of a section of the ESC 102, FIG. 3A provides a conceptual illustration of the thermally conductive cooling of the ESC caused by the chiller 302. For example, as shown in FIG. 3A, when the chiller 302 is activated, cooling fluid flows into the cooling channels 112 of the base plate 110. Thermally conductive cooling occurs which results in heat flowing toward the base plate 110 from the ceramic plate 106 and the annular heater setback region 203. As further illustrated in FIG. 3A, the figure provides a conceptual illustration of heat flowing from the outer heating element 206 toward the base plate 110 and the ceramic plate 106. The section of the ESC shown in FIG. 3A illustrates the base plate 110, the bond layer 108 disposed over the base plate 110, and the ceramic plate 106 disposed over the bond layer 108.

In the example shown, an outer diameter cooling channel 112a of the plurality of cooling channels is disposed below a portion of the bond layer 108, a portion of the ceramic plate 106, and the annular heater setback region 203. In one embodiment, the outer diameter cooling channel 112a may be partially under the annular heater setback region 203. In some embodiments, at least part of the outer diameter cooling channel 112a is located in a region of the base plate that is opposite the annular heater setback region 203 of the ceramic plate. In one embodiment, the outer diameter cooling channel 112a has a rectangular shape and a top portion of the rectangular shape is aligned horizontally below the annular heater setback region 203.

In some embodiments, the position of the cooling channels 112 within the base plate 110 forms an interface wall 314 that is adjacent to the bond layer 108. The interface wall 314 extends vertically from the top portion of the cooling channel 112 to the bottom surface of bond layer 108 and is defined by distance D3. In some embodiments, distance D3 can be about 3.6 mm. In other embodiments, the distance D3 of the interface wall 314 is not less than about 1 mm and not greater than about 6 mm. By maintaining interface wall 314 at a reduced thickness, it is possible to better influence thermally conductive cooling using the flow of the cooling fluid in the ceramic plate 106.

As further shown in FIG. 3A, in one embodiment, the outer heating element 206 is disposed between the bottom surface of the ceramic plate 106 and the bond layer 108. In some embodiments, the outer heating element 206 is inset from the annular heater setback region 203 of the ceramic plate 106 so that it does not interfere with the thermal conductive cooling from the cooling channels. For example, the outer heating element 206 configured such that it does not extend under the annular heater setback region 203 of the ceramic plate 106. This structural feature facilitates the thermally conductive cooling of the annular heater setback region 203 caused by the flow of the cooling fluid since the outer heating element 206 does not sit directly below the annular heater setback region 203 and interfere with the heat flowing towards the cooling channels 112.

In some embodiments, the bond layer 108 can be made out of a silicone material or any other type of material that has a high heat transfer coefficient to facilitate the thermally conductive cooling of the ceramic plate and also the annular heater setback region 203. The bond layer 108 may be defined by a thickness D2. Thickness D2 of the bond layer 108 extends from a bottom surface of the bond layer to a top surface of the bond layer. In one embodiment, the thickness D2 of the bond layer 108 can be about 0.75 mm In other embodiments, thickness D2 can range from about 0.1 mm and less than about 2 mm. In other embodiments, the thickness of D2 is set to be less than about 1 mm By maintaining reduced thicknesses of D2, it possible to improve the thermally conductive cooling caused by the flow of the cooling fluid in the baseplate 110.

As further shown in FIG. 3A, the ceramic plate 106 is disposed over the bond layer 108. The ceramic plate 106 includes the annular heater setback region 203 which is defined by a distance D1. When the annular heater setback region 203 is thermally conductively cooled by the flow of the cooling fluid in the base plate, a cold edge temperature region 308 is formed along the annular heater setback region 203 of the ceramic plate. As shown, distance D1 extends from the outer diameter of the raised top surface 216 to the outer diameter of the outer heating element 206. In one embodiment, distance D1 can range from about 2 mm and about 10 mm, or be any distance that is required for cooling the edges of the wafer 104. In some embodiments, the annular heater setback region 203 is disposed over a portion of the bond layer 108 and at least over part of the plurality of cooling channels 112 disposed along an outer diameter of the base plate 110. The thickness of the ceramic plate 106 is defined by D5. Thickness D5 extends from the bottom surface of ceramic plate 106 to the raised top surface 216 of the ceramic plate 106. In one embodiment, the thickness D5 of the ceramic plate 106 can be about 4.5 mm.

As further shown in FIG. 3A, during processing, the wafer 104 is supported by the raised top surface 216 of the ceramic plate 106. In some embodiments, when a wafer 104 is placed on the top surface of the ceramic plate, a wafer overhang portion 312 of the wafer 104 extends outward over the outer diameter of the raised top surface 216 by a distance D4. Distance D4 extends from the outer diameter of the raised top surface 216 to the wafer edge 304. In one embodiment, distance D4 can be about 2 mm.

In some embodiments, a temperature transition zone 310 exists at the boundary interface of the cold edge temperature region 308 and an annular area temperature zone 316 of the ceramic plate 106, e.g., the boundary interface between the outer diameter of the outer heating element and the annular heater setback region. As illustrated in FIG. 3A, when the chiller 302 is activated, a cooling fluid flows through the cooling channels 112 which cools the ceramic plate and the annular heater setback region 203 to a temperature value projected based on the chiller set point temperature. The thermal conductive cooling of the annular heater setback region 203 caused by the activation of the chiller 302 results in the cold edge temperature region 308 which in turn keeps a portion of the wafer 104 along its edges at a lower temperature relative to the rest of the wafer. As noted above, the outer heating element 206 is arranged in the annular area of the ESC 102.

When the outer heating element 206 produces heat, the outer heating element 206 heats the annular area of the ESC 102 which in turn results in the annular area temperature zone 316. As a result, a temperature transition zone 310 exists at the boundary of the cold edge temperature region 308 and the annular area temperature zone 316 of the ceramic plate 106. In some embodiments, the temperature gradient from the cold edge temperature region 308 to the annular area temperature zone 316 is uniform and gradually changes from one zone to another.

FIG. 3A-1 illustrates a temperature plot of the temperature regions of the ceramic plate 316 (e.g., cold edge temperature region 308, annular area temperature zone 316, central circular area temperature zone 320) and the corresponding temperature transition zone 310. As shown in the illustration, temperature is plotted along the Y-axis and the ceramic plate distance is plotted along the X-axis. The plot shows the temperature of the cold edge temperature region 308, the annular area temperature zone 316, and the central circular area temperature zone 320 ranging from about 12° C. to about In particular, the cold edge temperature region 308 is located at the annular heater setback region 203 which extends from an outer diameter of the raised top surface 216 of the ceramic plate 106 to the boundary interface 318 (e.g., outer diameter of the outer heating element 206). In one example, as shown, the temperature along cold edge temperature region 308 (e.g., D1) ranges from about 12° C. to about 18° C. In another embodiment, the annular area temperature zone 316 extends from the boundary interface 318 to the inner diameter of the outer heating element 206, and the temperature ranges from about 18° C. to about 20° C. The central circular area temperature zone 320 extends from the outer diameter of the inner heating element 204 to about the center point of the ceramic plate. It should be understood that the actual temperatures illustrated in FIG. 3A-1 are only examples, and the ranges will change depending on the process being run. The temperature transition zone 310 will be advantageously enabled by way of the structural design features discussed herein.

As further illustrated in FIG. 3A-1, the temperature transition zone 310 includes the boundary interface 318 which separates the cold edge temperature region 308 from the annular area temperature zone 316. In one embodiment, along the temperature transition zone 310, the temperature of the ceramic plate gradually increases from a lower temperature to a higher temperature because of the difference in the cooling and heating characteristics of the two regions. For example, the cold edge temperature region 308 does not have a heating element whereas the annular area temperature zone 316 includes the outer heating element. Instead of a stepwise or drastic temperature transition from one region to another, the temperature transition zone 310 illustrates a gradual and steady increase in temperature from the cold edge temperature region 308 to the annular area temperature zone 316. The temperature transition zone 310 includes a distance D6 which is a portion within the cold edge temperature region 308 and a distance D7 which is a portion within the annular area temperature zone 316. In one embodiment, distance D6 and distance D7 is about 2 mm.

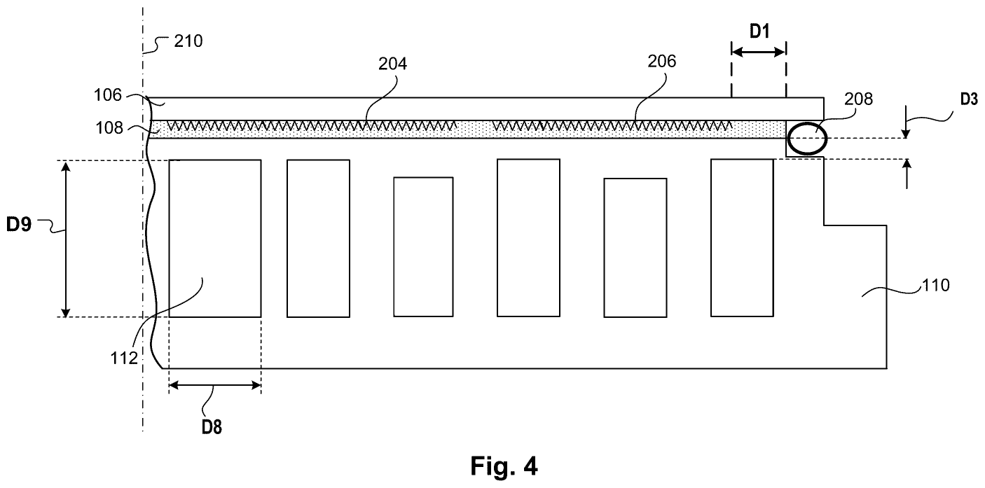

FIG. 4 illustrates an enlarged partial view of a section of the ESC 102 shown in FIG. 2B. In the illustrated embodiment, the ESC 102 includes the base plate 110 with a plurality of cooling channels 112 formed within the base plate, the bond layer 108 disposed over the base plate 110, and the ceramic plate 106 disposed over the bond layer 108. Each of the plurality of cooling channels 112 may have the same or different size, shape, geometry, volume, and surface area to facilitate the flow of the cooling fluid. For example, as illustrated in FIG. 4, the cooling channel near the centerline 210 of the base plate has a rectangular shape cross-section with a width D8 and a height D9. The width D8 and a height D9 of each cooling channel may be the same or vary, and depend on the thermally conductive cooling requirements of the ESC 102. In one example, width D8 can be about 9.0 mm and height D9 can be about 21 mm In another embodiment, as noted above, distance D3 is not less than about 1 mm and not greater than about 6 mm and extends from the top portion of the cooling channel 112 to the bottom surface of bond layer 108.

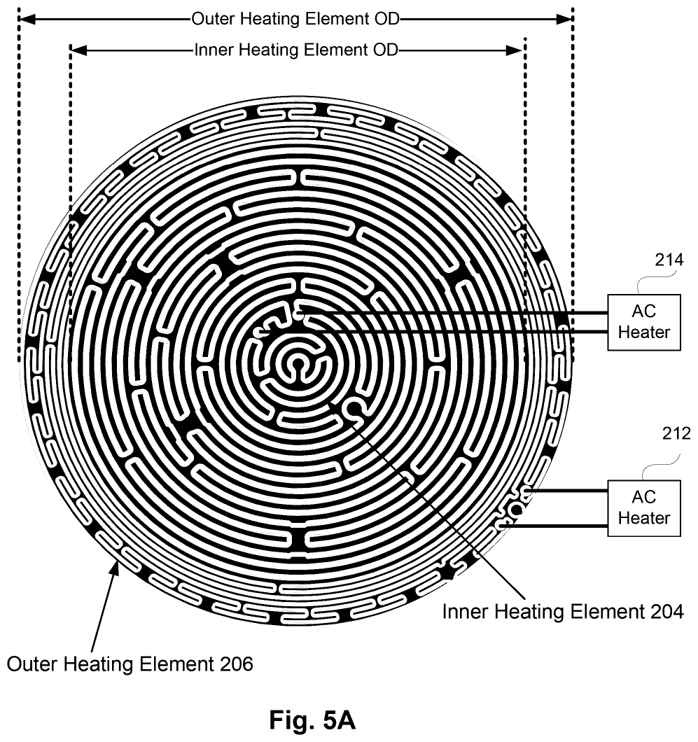

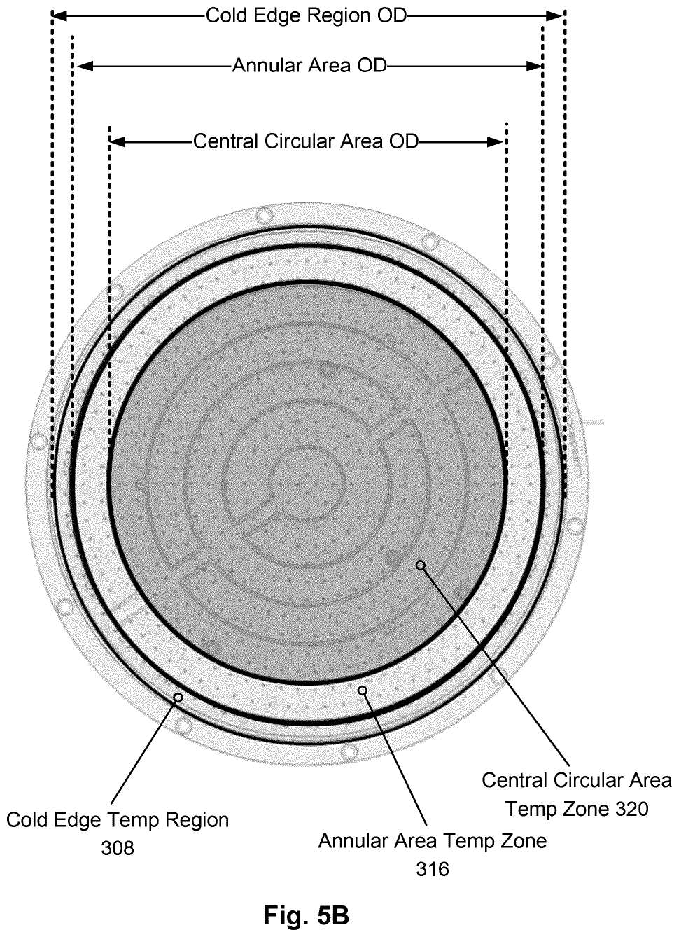

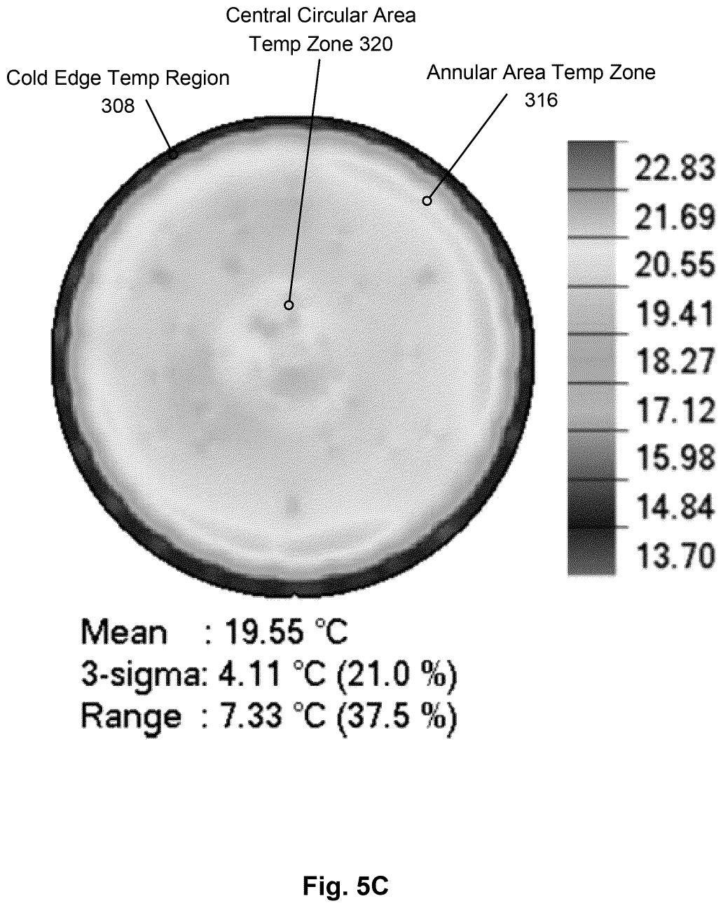

FIG. 5A illustrates an embodiment of a top view of the inner heating element 204 and the outer heating element 206. As noted above, the inner heating element 204 and the outer heating element 206 are disposed between the bottom surface of the ceramic plate 106 and the bond layer 108. The inner heating element 204 is arranged in a central circular area adjacent to the bottom surface of the ceramic plate 106. In the illustrated example, the inner heating element 204 begins at a point proximate to a center point of the ESC 102 and extends circularly outward resulting in the inner heating element 204 having an outer diameter of about 230 mm. The outer heating element 206 is arranged in an annular area that surrounds the central circular area and is adjacent to the bottom surface of the ceramic plate 106. In some embodiments, the outer heating element 206 extends circularly outward toward the periphery of the ESC 102 and has an inner diameter of about 236 mm and an outer diameter of about 285 mm.

As further illustrated in FIG. 5A, the AC heater 212 is connected to input and output connections of the outer heating element 206, and the AC heater 214 is connected to input and output connections of the inner heating element 204. The AC heater 212 and the AC heater 214 are configured to deliver power to the respective heating elements. When the AC heaters are activated, the inner heating element 204 and the outer heating element 206 produces heat which in turn creates a central circular area temperature zone 320 and an annular area temperature zone 316 within the ceramic plate 106, respectively. As noted above, only two heaters, reduces the complexity of the design and assists in reducing costs associated with added components such as alternating current (AC) boxes, control systems, heater RF filters, etc.

FIG. 5B illustrates an embodiment of a top view of the ESC 102 showing the various temperature zones in the ESC 102. In one embodiment, the ESC 102 may have a cold edge temperature region 308, an annular area temperature zone 316, and a central circular area temperature zone 320. The cold edge temperature region 308 is located along the periphery of the ceramic plate 106. The cold edge temperature region 308 is controlled by the chiller set point which creates an indirect temperature tuning zone without the heaters. In one embodiment, the cold edge temperature region 308 has an inner diameter of about 285 mm and an outer diameter of about 295 mm. As noted above, the cold edge temperature region 308 is within the annular heater setback region 203 of the ceramic plate 106. In one embodiment, the cold edge temperature region 308 is created when the chiller 302 is activated to operate at a set point temperature. Cooling fluid then flows through the cooling channels 112 and causes thermally conductive cooling in the annular heater setback region 203 of the ceramic plate 106.

In one embodiment, the shape and contact surface area of the cooling channels 112 may help contribute to the thermally conductive cooling of the annular heater setback region 203 to create the cold edge temperature region 308. For example, cooling channels 112 having a rectangular shaped cross-section that have a greater width and height compared to traditional designs results in a greater contact surface area for the fluid to contact. This may result in an improved heat transfer coefficient and result in an increase in thermally conductive cooling of the annular heater setback region 203 and other regions of the ceramic plate.

In another embodiment, the bond layer 108 being reduced in thickness may help contribute to the thermally conductive cooling of the annular heater setback region 203. For example, a bond layer with a thickness that is reduced by half may result in a doubled heat transfer coefficient which in turn results facilitates the thermally conductive cooling of the annular heater setback region 203 and other regions of the ceramic plate. Accordingly, during processing of the wafer 104, the cold edge temperature region 308 is controlled by the chiller set point temperature which controls the temperature of the portion of the wafer that is along the cold edge temperature region. Controlling the temperature of the wafer 104 and keeping it at a desired temperature can help assist improve etch rate and uniformity on the wafer to meet requirements for bottom critical dimension (CD) profiles of etched features.

In some embodiments, the annular area temperature zone 316 has an inner diameter of about 236 mm and an outer diameter of about 285 mm In one embodiment, the annular area temperature zone 316 is created when the AC heater 212 delivers power to the outer heating element 206 which in turn produces heat. In another embodiment, the central circular area temperature zone 320 begins at a point proximate to the center point of the ESC 102 and has an outer diameter of about 231 mm In one embodiment, the central circular area temperature zone 320 is created when the AC heater 214 delivers power to the inner heating element 204 which in turn produces heat.

Accordingly, the ESC 102 may have three temperature zones, e.g., cold edge temperature region 308, annular area temperature zone 316, and central circular area temperature zone 320. Since the annular heater setback region 203 does not have any heating elements extending below its region, the cold edge temperature region 308 relies passively on the thermally conductive cooling caused by the chiller set point temperature and the flow of the cooling fluid circulating through the base plate cooling channels. The annular area temperature zone 316 and the central circular area temperature zone are influenced by the respective outer heating element 206 and the inner heating element 204, and also the thermally conductive cooling caused by the chiller. This three-temperature zone configuration can result in a reduction in system and operating costs since the number of components that are required to operate the ESC 102 is reduced.

FIG. 5C illustrates an embodiment of a top view of the ESC 102 showing the heat transfer simulation results of the ESC 102. In one example, the heat transfer simulation shows the temperature of the ESC 102 ranging from about 13.7° C. to about 22.8° C. In one embodiment, the cold edge temperature region 308 which has an inner diameter of about 285 mm and an outer diameter of about 295 mm has a temperature about 13.7° C. In another embodiment, the annular area temperature zone 316 which has an inner diameter of about 236 mm and an outer diameter of about 285 mm has a temperature that ranges about 21.0° C. and about 14.0° C. In another embodiment, the central circular area temperature zone 320 which begins at a point proximate to the center point of the ESC 102 and has an outer diameter of about 231 mm has a temperature about 20.0° C.

In general, since the central circular area temperature zone 320 and the annular area temperature zone 316 are influenced by the combination of the chiller and the heating elements, and the cold edge temperature region 308 is influenced primarily by the cooling effects caused by the chiller, the cold edge temperature region 308 will generally be at a lower temperature or at an equal temperature relative to the central circular area temperature zone 320 and the annular area temperature zone 316. The temperatures shown in FIG. 5C are only by way of example, and it should be understood that the actual temperatures will vary depending on the process being run, including power settings, chiller settings, etc. However, the temperature plot is useful to illustrate how the cold edge is controlled relative to other parts of the ESC.

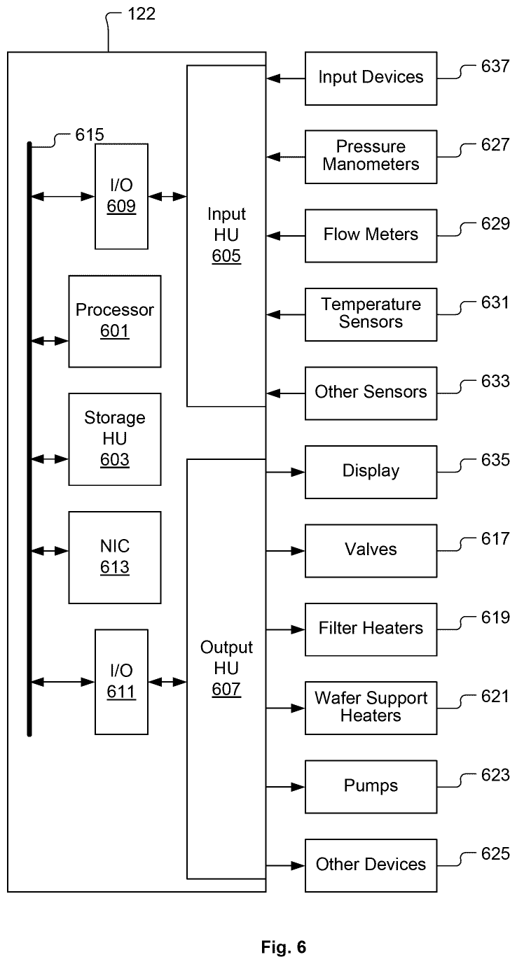

FIG. 6 shows an example schematic of the control system 122 of FIG. 1A, in accordance with some embodiments. Although not shown, a similar control system 122 is used in the TCP system of FIG. 1B. In some embodiments, the control system 122 is configured as a process controller for controlling the semiconductor fabrication process performed in a plasma processing system. In various embodiments, the control system 122 includes a processor 601, a storage hardware unit (HU) 603 (e.g., memory), an input HU 605, an output HU 607, an input/output (I/O) interface 609, an I/O interface 611, a network interface controller (NIC) 613, and a data communication bus 615. The processor 601, the storage HU 603, the input HU 605, the output HU 607, the I/O interface 609, the I/O interface 611, and the NIC 613 are in data communication with each other by way of the data communication bus 615. The input HU 605 is configured to receive data communication from a number of external devices. Examples of the input HU 605 include a data acquisition system, a data acquisition card, etc. The output HU 607 is configured to transmit data to a number of external devices.

An example of the output HU 607 is a device controller. Examples of the NIC 613 include a network interface card, a network adapter, etc. Each of the I/O interfaces 609 and 611 is defined to provide compatibility between different hardware units coupled to the I/O interface. For example, the I/O interface 609 can be defined to convert a signal received from the input HU 605 into a form, amplitude, and/or speed compatible with the data communication bus 615. Also, the I/O interface 607 can be defined to convert a signal received from the data communication bus 615 into a form, amplitude, and/or speed compatible with the output HU 607. Although various operations are described herein as being performed by the processor 601 of the control system 122, it should be understood that in some embodiments various operations can be performed by multiple processors of the control system 122 and/or by multiple processors of multiple computing systems in data communication with the control system 122.

In some embodiments, the control system 122 is employed to control devices in various wafer fabrication systems based in-part on sensed values. For example, the control system 122 may control one or more of valves 617, filter heaters 619, wafer support structure heaters 621, pumps 623, and other devices 625 based on the sensed values and other control parameters. The valves 617 can include valves associated with control of a backside gas supply system, a process gas supply system, and a temperature control fluid circulation system. The control system 122 receives the sensed values from, for example, pressure manometers 627, flow meters 629, temperature sensors 631, and/or other sensors 633, e.g., voltage sensors, current sensors, etc. The control system 122 may also be employed to control process conditions within the plasma processing system during performance of plasma processing operations on the wafer 104. For example, the control system 122 can control the type and amounts of process gas(es) supplied from the process gas supply system to the plasma process chamber. Also, the control system 122 can control operation of a DC supply for the clamp electrode(s) 202. The control system 122 can also control operation of a lifting device for the lift pins. The control system 122 also controls operation of the backside gas supply system and the temperature control fluid circulation system. The control system 122 also controls operation of pump 126 that controls removal of gaseous byproducts from the chamber 118. It should be understood that the control system 122 is equipped to provide for programmed and/or manual control any function within the plasma processing system.

In some embodiments, the control system 122 is configured to execute computer programs including sets of instructions for controlling process timing, process gas delivery system temperature, and pressure differentials, valve positions, mixture of process gases, process gas flow rate, backside cooling gas flow rate, chamber pressure, chamber temperature, wafer support structure temperature (wafer temperature), RF power levels, RF frequencies, RF pulsing, impedance matching system settings, cantilever arm assembly position, bias power, and other parameters of a particular process. Other computer programs stored on memory devices associated with the control system 122 may be employed in some embodiments. In some embodiments, there is a user interface associated with the control system 122. The user interface includes a display 635 (e.g., a display screen and/or graphical software displays of the apparatus and/or process conditions), and user input devices 637 such as pointing devices, keyboards, touch screens, microphones, etc.

Software for directing operation of the control system 122 may be designed or configured in many different ways. Computer programs for directing operation of the control system 122 to execute various wafer fabrication processes in a process sequence can be written in any conventional computer readable programming language, for example: assembly language, C, C++, Pascal, Fortran or others. Compiled object code or script is executed by the processor 601 to perform the tasks identified in the program. The control system 122 can be programmed to control various process control parameters related to process conditions such as, for example, filter pressure differentials, process gas composition and flow rates, backside cooling gas composition and flow rates, temperature, pressure, plasma conditions, such as RF power levels and RF frequencies, bias voltage, cooling gas/fluid pressure, and chamber wall temperature, among others. Examples of sensors that may be monitored during the wafer fabrication process include, but are not limited to, mass flow control modules, pressure sensors, such as the pressure manometers 627 and the temperature sensors 631. Appropriately programmed feedback and control algorithms may be used with data from these sensors to control/adjust one or more process control parameters to maintain desired process conditions.

In some implementations, the control system 122 is part of a broader fabrication control system. Such fabrication control systems can include semiconductor processing equipment, including a processing tools, chambers, and/or platforms for wafer processing, and/or specific processing components, such as a wafer pedestal, a gas flow system, etc. These fabrication control systems may be integrated with electronics for controlling their operation before, during, and after processing of the wafer. The control system 122 may control various components or subparts of the fabrication control system. The control system 122, depending on the wafer processing requirements, may be programmed to control any of the processes disclosed herein, including the delivery of processing gases, the delivery of backside cooling gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the control system 122 may be defined as electronics having various integrated circuits, logic, memory, and/or software that receive instructions, issue instructions, control operation, enable wafer processing operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the control system 122 in the form of various individual settings (or program files), defining operational parameters for carrying out a particular process on the wafer within the system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The control system 122, in some implementations, may be a part of or coupled to a computer that is integrated with, coupled to the plasma processing system, or otherwise networked to the system, or a combination thereof. For example, the control system 122 may be in the “cloud” of all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to the system over a network, which may include a local network or the Internet.

The remote computer may include a user interface that enables entry or programming of parameters and/or settings, which are then communicated to the system from the remote computer. In some examples, the control system 122 receives instructions in the form of data, which specify parameters for each of the processing steps to be performed during one or more operations. It should be understood that the parameters may be specific to the type of process to be performed within the plasma processing system. Thus, as described above, the control system 122 may be distributed, such as by comprising one or more discrete controllers that are networked together and working towards a common purpose, such as the processes and controls described herein. An example of a distributed controller for such purposes would be one or more integrated circuits on the plasma processing system in communication with one or more integrated circuits located remotely (such as at the platform level or as part of a remote computer) that combine to control a process performed on the plasma processing system.

Without limitation, example systems that the control system 122 can interface with may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers. As noted above, depending on the process step or steps to be performed by the tool, the control system 122 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Embodiments described herein may also be implemented in conjunction with various computer system configurations including hand-held hardware units, microprocessor systems, microprocessor-based or programmable consumer electronics, minicomputers, mainframe computers and the like. Embodiments described herein can also be implemented in conjunction with distributed computing environments where tasks are performed by remote processing hardware units that are linked through a network. It should be understood that the embodiments described herein, particularly those associated with the control system 122, can employ various computer-implemented operations involving data stored in computer systems. These operations are those requiring physical manipulation of physical quantities. Any of the operations described herein that form part of the embodiments are useful machine operations. The embodiments also relate to a hardware unit or an apparatus for performing these operations. The apparatus may be specially constructed for a special purpose computer. When defined as a special purpose computer, the computer can also perform other processing, program execution or routines that are not part of the special purpose, while still being capable of operating for the special purpose. In some embodiments, the operations may be processed by a general purpose computer selectively activated or configured by one or more computer programs stored in the computer memory, cache, or obtained over a network. When data is obtained over a network, the data may be processed by other computers on the network, e.g., a cloud of computing resources.

Various embodiments described herein can be implemented through process control instructions instantiated as computer-readable code on a non-transitory computer-readable medium. The non-transitory computer-readable medium is any data storage hardware unit that can store data, which can be thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes, and other optical and non-optical data storage hardware units. The non-transitory computer-readable medium can include computer-readable tangible medium distributed over a network-coupled computer system so that the computer-readable code is stored and executed in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

1. An electrostatic chuck, comprising:
a base plate;
a bond layer disposed over the base plate;
a ceramic plate having a bottom surface disposed over the bond layer, the ceramic plate having a raised top surface for supporting a substrate, the raised top surface having an outer diameter; and
a heater disposed between the bottom surface of the ceramic plate and the bond layer, the heater includes an inner heating element and an outer heating element, said inner heating element is arranged in a central circular area adjacent to the bottom surface of the ceramic plate and said outer heating element is arranged in an annular area that surrounds the central circular area and is adjacent to the bottom surface of the ceramic plate, wherein an outer diameter of the outer heating element is inset from an annular heater setback region of the ceramic plate, the annular heater setback region is between the outer diameter of the raised top surface and the outer diameter of the outer heating element;
wherein the base plate includes a plurality of cooling channels, said plurality of cooling channels are disposed below the inner heating element, below the outer heating element, and below the annular heater setback region, and each of said plurality of cooling channels is configured to flow a cooling fluid to cause thermally conductive cooling in the annular heater setback region of the ceramic plate.

2. The electrostatic chuck of claim 1, wherein the plurality of cooling channels are arranged to circulate said cooling fluid in said base plate, wherein an outer diameter cooling channel of the plurality of cooling channels is disposed below said annular heater setback region

3. The electrostatic chuck of claim 2, wherein said outer diameter cooling channel has a rectangular shape formed within the base plate, a top portion of the rectangular shape is aligned horizontally below said annular heater setback region.

4. The electrostatic chuck of claim 2, wherein said outer diameter cooling channel forms an interface wall adjacent to said bond layer and below said annular heater setback region.

5. The electrostatic chuck of claim 4, wherein said interface wall has a dimension of not less than about 1 mm and not greater than about 6 mm.

6. The electrostatic chuck of claim 1, wherein said heater is bonded to said bottom surface of the ceramic plate.

7. The electrostatic chuck of claim 1, wherein said bond layer has a thickness of between about 0.1 mm and less than about 2 mm.

8. The electrostatic chuck of claim 7, wherein said bond layer has a thickness of about 0.75 mm.

9. The electrostatic chuck of claim 1, wherein said annular heater setback region is between about 2 mm and about 10 mm.

10. The electrostatic chuck of claim 2, wherein said outer diameter cooling channel of the plurality of cooling channels being disposed below said annular heater setback region places at least part of said outer diameter cooling channel in a region of the base plate that is opposite the annular heater setback region of the ceramic plate.

11. The electrostatic chuck of claim 1, wherein said bond layer is disposed between the base plate and the annular heater setback region of the ceramic plate to provide said thermally conductive cooling of the annular heater setback region of the ceramic plate using said cooling fluid.

12. The electrostatic chuck of claim 1, said thermally conductive cooling of the annular heater setback region of the ceramic plate provides for a cold edge region for the substrate, when the substrate is disposed over the raised top surface.

13. The electrostatic chuck of claim 1, wherein a temperature transition zone is provided in the ceramic plate at an interface between the outer diameter of the outer heating element and the annular heater setback region, wherein the annular heater setback region is setback away from the outer diameter of the outer heating element.

14. The electrostatic chuck of claim 1, wherein the outer heating element does not extend under said annular heater setback region of the ceramic plate, and said annular heater setback region of the ceramic plate is disposed over a portion of the bond layer, and at least over part of one of the plurality of cooling channels disposed along an outer diameter of the base plate.

15. A method for thermally cooling a region of an electrostatic chuck, the electrostatic chuck including a ceramic plate and a base plate, comprising
providing an inner heating element and an outer heating element between the base plate and the ceramic plate, wherein the outer heating element is positioned away from an annular heater setback region of the ceramic plate;
flowing a cooling fluid along a plurality of cooling channels disposed in the base plate, wherein at least one of the plurality of cooling channels is disposed under the annular heater setback region, the cooling fluid is configured to cause thermal cooling in the annular heater setback region of the ceramic plate to provide for a cold edge region for a substrate when disposed over the electrostatic chuck;
activating alternating current (AC) heaters that are connected to the outer heating element and the inner heating element; and
activating a chiller to operate at a set point temperature, said activating the chiller is configured to control flow of the cooling fluid to thermally cool the ceramic plate and the annular heater setback region.

16. The method as recited in claim 15, further comprising,
operating a controller to manage control of the chiller to operate at said set point temperature.

17. The method as recited in claim 15, further comprising,
arranging the plurality of cooling channels in said base plate to circulate said cooling fluid, wherein an outer diameter cooling channel of the plurality of cooling channels is disposed below said annular heater setback region.

18. The method as recited in claim 15, further comprising,
providing a bond layer over the base plate, said bond layer has a thickness of between about 0.1 mm and less than about 2 mm.

19. The method of claim 15, further comprising:
measuring temperature data related to the annular heater setback region of the ceramic plate, and
determining if the temperature data is within a temperature value projected based on the set point temperature.
